(19) United States
(12) Patent Application Publication
(10) Pub. No.: US 2018/0063983 A1
(43) Pub. Date: Mar. 1, 2018

(54) BOARD FIXING STRUCTURE

(71) Applicant: AISIN SEIKI KABUSHIKI KAISHA, Kariya-shi (JP)

(72) Inventors: Shinsuke ANDO, Anjo-shi (JP); Masakazu NAKAMURA, Nagoya-shi (JP)

(73) Assignee: AISIN SEIKI KABUSHIKI KAISHA, Kariya-shi (JP)

(21) Appl. No.: 15/477,627

(22) Filed: Apr. 3, 2017

(30) Foreign Application Priority Data
Aug. 25, 2016 (JP) 2016-164744

(51) Int. Cl. H05K 7/14

(52) U.S. Cl. CPC H05K 7/1417; H05K 3/301; H05K 7/1422

(57) ABSTRACT

A board fixing structure includes: a resin-made holder; a metal-made terminal held by the holder; and a circuit board connected to the terminal, in which the terminal has a proximal end portion, a fixing portion extending from the proximal end portion and fixedly soldered to the circuit board, and a support portion extending from the proximal end portion and coming into contact with a rear surface of the circuit board so as to support the circuit board, and the fixing portion and the support portion are separated from each other in a plane direction of the circuit board.

### CROSS REFERENCE TO RELATED APPLICATIONS

This application is based on and claims priority under 35 U.S.C. §119 to Japanese Patent Application 2016-164744, filed on Aug. 25, 2016, the entire contents of which are incorporated herein by reference.

### TECHNICAL FIELD

This disclosure relates to a board fixing structure including a resin-made holder and a circuit board connected to a metal-made terminal.

### BACKGROUND DISCUSSION

As a board fixing structure in the related art, a technique has been used in which a circuit board is fixed to a holder by means of screwing and a metal claw disposed in the holder is fixed to the circuit board by means of caulking (refer to background discussion in JP 2007-149747A (Reference 1)).

On the other hand, as another board fixing structure, according to the disclosure in Reference 1, a terminal (board fixing pin in Reference 1) formed from a pin-shaped metal piece is fixed to the holder (resin case in Reference 1) by means of insert molding. An end portion of the terminal is inserted into a throughhole disposed in the circuit board, and is soldered thereto.

According to the disclosure in JP 10-303522A (Reference 2), an L-shaped or a cross-shaped projection is disposed in a terminal (external connection terminal in Reference 2) in which a metal plate serving as a wire of a circuit board is bent. The projection is brought into contact with a rear surface of another circuit board so as to support another circuit board.

However, according to the method of fixing the circuit board by means of screwing or caulking as in the related art, in order to avoid the influence caused by stress applied to a screw fixing area or caulking area, an electronic component cannot be mounted on these areas. Consequently, board mounting density decreases.

On the other hand, if the terminal is soldered to the circuit board as in Reference 1, the board mounting density can increase. However, a thermal expansion coefficient of a resin configuring the holder is greater than a thermal expansion coefficient of metal configuring the terminal. Accordingly, thermal stress is likely to be applied in a direction in which the terminal is inclined, and the stress is concentrated on a soldered portion, thereby causing a possibility that the soldered portion may be broken.

Only if the circuit board is supported by bringing the projection of the terminal into contact with the rear surface of the circuit board as in Reference 2, the circuit board is not sufficiently fixed. Even in a case where the terminal is soldered to the circuit board, soldering heat (heat applied to the solder) tends to escape to the terminal via the projection, and the solder insufficiently melted, thereby causing a possibility that the circuit board may be unsatisfactorily fixed.

Thus, a need exists for a board fixing structure which is not susceptible to the drawback mentioned above.

### SUMMARY

A feature of a board fixing structure according to an aspect of this disclosure resides in that the board fixing structure includes a resin-made holder, a metal-made terminal held by the holder, and a circuit board connected to the terminal, the terminal has a proximal end portion, a fixing portion extending from the proximal end portion and fixedly soldered to the circuit board, and a support portion extending from the proximal end portion and coming into contact with a rear surface of the circuit board so as to support the circuit board, and the fixing portion and the support portion are separated from each other in a plane direction of the circuit board.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is a schematic side view of a vehicle sensor;

FIG. 2 is a perspective view of a conductive member;

FIG. 3 is a view taken in a direction of arrow III-III n FIG. 1;

FIG. 4 is a perspective view of a conductive member according to another embodiment; and

FIG. 5 is a plan view of a circuit board according to another embodiment.

### DETAILED DESCRIPTION

Hereinafter, embodiments of a board fixing structure according to this disclosure will be described with reference to the drawings. In the embodiments disclosed here, an example of a board fixing structure of a vehicle sensor X used for a vehicle will be described. However, without being limited to the following embodiments, various modifications are available within the scope not departing from the gist of the embodiments disclosed here.

The vehicle sensor X is configured to include a position detection sensor of a transmission, a rotation speed sensor, a load detection sensor of a brake pedal, and a current sensor of an in-vehicle motor, and outputs a detection signal of a detection element to an electronic control unit (ECU).

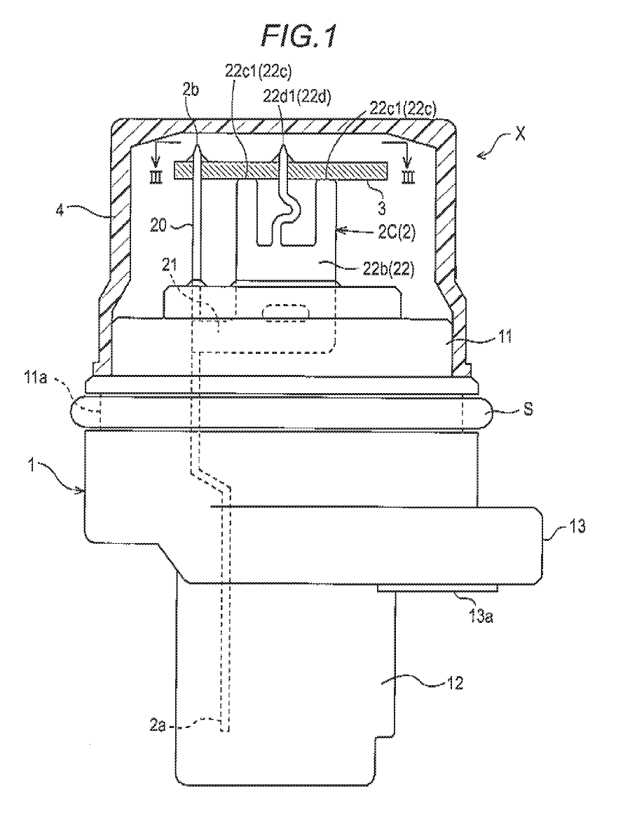

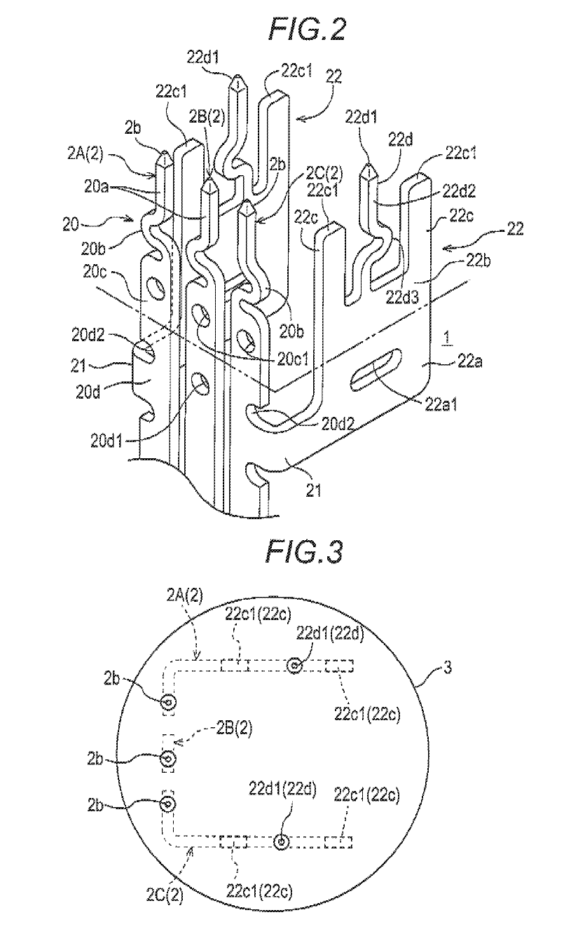

FIG. 1 illustrates a schematic side view (partial sectional view) of the vehicle sensor X according to the embodiment disclosed here. FIG. 2 illustrates a perspective view of a conductive member 2 located inside the vehicle sensor X. FIG. 3 illustrates a plan view of a circuit board 3 located inside the vehicle sensor X, and illustration of an electronic component connected to the conductive member 2 is omitted.

As illustrated in FIG. 1, the vehicle sensor X includes a r lade holder 1, the metal-made conductive member 2 insert-molded so as to be held by the holder 1, and the circuit board 3 which is electrically connected to the conductive member 2 and in which an electronic component (not illustrated) is mounted on an insulating board. The circuit board 3 in the embodiment disclosed here is fixed to the holder 1 via the conductive member 2. As a resin configuring the holder 1, nylon is used. As metal configuring the conductive member 2, copper is used. However, the material is not particularly limited.

The holder 1 has a columnar main body 11, a tubular portion 12 extending while being reduced in diameter from the main body 11, and a flange portion 13 adjacent to the tubular portion 12 and formed to protrude radially outward from the main body 11. A lid member 4 is fixed to the main body 11 of the holder 1 by means of press fitting and screwing, and the circuit board 3 is hermetically sealed. A seal groove 11a having a seal member S mounted for sealing is formed at a center in an axial direction of the main body 11 (center in a vertical direction in FIG. 1). The seal member S is mounted thereon so as to prevent water from entering the inside of the lid member 4 when the lid member 4 side of the vehicle sensor X is inserted into a housing (not illustrated) for accommodating various components of a vehicle.

The tubular portion 12 is located on a side opposite to the circuit board 3 in the holder 1. A connector (not illustrated) which supplies driving power to a control circuit (not illustrated) of the circuit board 3 and to which a detection signal is output from the control circuit is connected to the tubular portion 12. In an exposed state, one end portion 2a of the conductive member 2 connected to the connector is accommodated inside the tubular portion 12. A hole portion 13a to be fastened and fixed to the housing of the vehicle by using bolts is formed to penetrate the flange portion 13.

As illustrated in FIG. 2, the conductive member 2 is configured so that a plurality of (three in the embodiment disclosed here) first conductive member 2A, second conductive member 2B, and third conductive member 2C to each of which an electric signal is transmitted are separated from each other. In a plurality of the conductive members 2A to 2C, one end portion 2a is connected to a connector, and the other end portion 2b is fixed to the circuit board 3 by means of soldering (refer to FIG. 1).

In a plurality of the conductive members 2A to 2C, the other end portion 2b of a first portion 20 formed in a pin shape is fixed to the circuit board 3. The other end portion 2b is electrically connected to an electronic component of the circuit board 3, and the electric signal is transmitted to the other end portion 2b. From the other end portion 2b side, the first portion 20 is configured to sequentially include a linear portion 20a, a curved portion 20b curved in an arc shape from the linear portion 20a, an enlarged diameter portion 20c whose diameter is enlarged from the linear portion 20a, and an insert portion 20d extending with the same width as that of the enlarged diameter portion 20c and insert-molded to the holder 1. That is, the linear portion 20a and the curved portion 20b curved from the linear portion 20a are formed between the other end portion 2b of the conductive members 2A to 2C and the holder 1. A pilot hole 20c1 used when the conductive member 2 is subjected to press working is disposed in the enlarged diameter portion 20c exposed from the holder 1. A through-hole 20d1 or a groove portion 20d2 is formed in the insert portion 20d.

In a plurality of the conductive members 2A to 2C, the first conductive member 2A and the third conductive member 2C which are located on both ends have a flat plate-shaped second portion 22 (example of a terminal) which is integrated from the first portion 20 via a connection portion 21. The second portion 22 is configured to include an insert portion 22a (proximal end portion, example of a portion present inside the holder 1) connected to the connection portion 21 and insert-molded to the holder 1, an exposed portion 22b (example of a proximal end portion) extending with the same width as that of the insert portion 22a and exposed from the holder 1, a bifurcated portion 22c (example of a support portion) extending in a bifurcated shape from the exposed portion 22b, and a pin-shaped small diameter portion 22d (example of a fixing portion) extending from the exposed portion 22b and having a smaller diameter than that of the bifurcated portion 22c.

A through-hole 22a1 is formed in the insert portion 22a present inside the holder 1. A center of the through-hole 22a1 of the first conductive member 2A and the third conductive member 2C is located on the same plane parallel to a plane of the circuit board 3. The center of the through-hole 22a1 of the first conductive member 2A and the third conductive member 2C is located on the same plane with respect to the center of the through-hole 20d1 or the groove portion 20d2 of the insert portion 20d of the first portion 20 in the conductive members 2A to 2C,

The bifurcated portion 22c is disposed on the same plane as that of the insert portion 22a and the exposed portion 22b. Two contact portions 22c1 coming into contact with a rear surface of the circuit board 3 so as to support the circuit board 3 are formed in an end portion of the bifurcated portion 22c. The small diameter portion 22d is disposed on the same plane as that of the bifurcated portion 22e, between the bifurcated portions 22c. A distal end portion 22d1 of the small diameter portion 22d is fixed to the circuit board 3 by means of soldering (refer to FIG. 3). According to the embodiment disclosed here, the distal end portion 22d1 of the small diameter portion 22d is not electrically connected to the electric component of the circuit board 3, and has a function only to fix the circuit board 3. As illustrated in FIGS. 2 and 3, the small diameter portion 22d of the second portion 22 in the first conductive member 2A and the third conductive member 2C, which serves as a fixing portion, and the bifurcated portion 22c of the second portion 22, which serves as a support portion, are separated from each other in a plane direction of the circuit board 3.

As illustrated in FIG. 2, from the distal end portion 22d1 side, the small diameter portion 22d is configured to sequentially include a linear portion 22d2 and a curved portion 22d3 (example of a bent portion) curved in an arc shape from the linear portion 22d2. That is, the linear portion 22d2 and the curved portion 22d3 curved from the linear portion 22d2 are formed between the distal end portion 22d1 of the small diameter portion 22d in the first conductive member 2A and the third conductive member 2C and the holder 1. According to the embodiment disclosed here, the curved portions 20b and 22d3 of the first portion 20 and the small diameter portion 22d are separated so as not to come into contact with the rear surface of the circuit board 3 (refer to FIG. 1). The curved portions 20b and 22d3 of the first portion 20 and the small diameter portion 22d which are described above may not be formed in the arc shape. Both of these may be formed to be curved in a U-shape. A side of the circuit board 3 side may be omitted from the enlarged diameter portion 20c in the first portion 20 of the first conductive member 2A and the third conductive member 2C, and the small diameter portion 22d of the second portion 22 may be electrically connected to the electronic component of the circuit board 3.

As described above, the small diameter portion 22d of the second portion 22 in the first conductive member 2A and the third conductive member 2C, which serves as the fixing portion fixedly soldered to the circuit board 3, and the bifurcated portion 22c of the second portion 22 in the first conductive member 2A and the third conductive member 2C, which supports the circuit board 3, are configured to have the same terminal member. As a result, the number of components and the processing cost can be saved. Moreover, the board fixing structure includes the bifurcated portion 22c coming into contact with the rear surface of the circuit board 3 so as to support the circuit board 3. Accordingly, the circuit board 3 can be fixed in a stabilized state. As a result, even in a case where an external force which causes misalignment to the circuit board 3 is applied due to thermal expansion, a bending force applied to the small diameter portion 22d is received by the bifurcated portion 22c. Therefore, the soldered portion is less likely to be broken.

According to the embodiment disclosed here, the circuit board 3 is supported by the bifurcated portion 22c at a position different from that of the small diameter portion 22d. Accordingly, it is possible to prevent a disadvantage that soldering heat may escape via the bifurcated portion 22c. As a result, the solder is properly melted. Therefore, the circuit board 3 can be satisfactorily fixed. The first portion 20 of the conductive members 2A to 2C to be soldered to the circuit board 3, and the small diameter portion 22d of the second portion 22 of the first conductive member 2A and the third conductive member 2C are formed in a pin shape. Accordingly, heat capacity is small, and the soldering heat is less likely to escape therefrom. Moreover, if the curved portions 20b and 22d3 are formed in the first portion 20 of the conductive members 2A to 2C and the small diameter portion 22d of the second portion 22 of the first conductive member 2A and the third conductive member 2C, the curved portions 20b and 22d3 restrain the soldering heat from being transferred to the enlarged diameter portion 20c or the exposed portion 22b. Therefore, the circuit board 3 can be more satisfactorily fixed.

The curved portions 20b and 22d3 according to the embodiment disclosed here are separated from the circuit board 3. Accordingly, the curved portions 20b and 22d3 do not come into contact with the circuit board 3, and a function of the bifurcated portion 22c to support the circuit board 3 is not impaired.

According to the embodiment disclosed here, the center of the through-hole 22a1 of the second portion 22 insert-molded to the holder 1, and the center of the through-hole 20d1 or the groove portion 20d2 of the first portion 20 are set on the same plane parallel to the plane of the circuit board 3. As a result, since the resin circumferentially enters the same height from the circuit board 3, starting points of thermal expansion of the conductive members 2 can be aligned at the same height. That is, a dimensional change amount of the conductive members 2 due to the thermal expansion can be equalized. Therefore, without causing the circuit board 3 to be deflected, the soldered portion can be prevented from being broken.

As in the embodiment disclosed here, if the small diameter portion 22d to be soldered and fixed is disposed between the bifurcated portions 22c of the second portion 22, both sides of the small diameter portion 22d are supported by the bifurcated portions 22c. Accordingly, the support balance is improved, and the circuit board 3 can be more satisfactorily fixed. As illustrated in FIG. 3, according to the embodiment disclosed here, the bifurcated portion 22c of the second portion 22 is disposed to be line-symmetrical to the second conductive member 2B located at the center of a plurality of the conductive members 2A to 2C. Therefore, it is possible to reliably restrain the circuit board 3 from being inclined.

### Other Embodiments

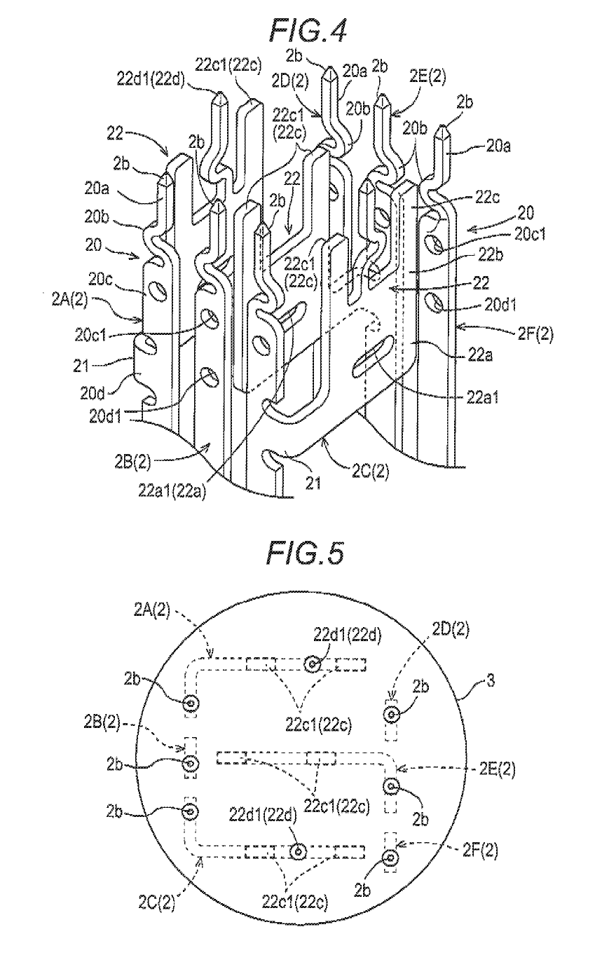

(1) The above-described embodiment adopts a configuration including three conductive members 2A to 2C. However, as illustrated in FIGS. 4 and 5, a configuration including six conductive members 2A to 2F may be adopted. In this case, for example, a signal can be output from two sensor elements. In the embodiment illustrated in FIGS. 4 and 5, the fourth conductive member 2D and the sixth conductive member 2F have the same configuration as that of the second conductive member 2B. The small diameter portion 22d of the first conductive member 2A is omitted from the fifth conductive member 2E. In this case, the circuit board 3 can be supported by the bifurcated portions 22c at six locations. Therefore, the circuit board 3 can be fixed in a further stabilized state.

(2) A configuration of the first conductive member 2A, a configuration of the second conductive member 2B, and a configuration of the fifth conductive member 2E in the above-described embodiment may be appropriately combined with each other. As described above, a configuration may be combined therewith in which a side of the circuit board 3 is omitted from the enlarged diameter portion 20c in the first portion 20 of the first conductive member 2A, and in which the small diameter portion 22d of the second portion 22 is electrically connected to the electronic component of the circuit board 3.

(3) In the above-described embodiment, the curved portions 20b and 22d3 are disposed in the conductive members 2A to 2F. However, without disposing the curved portion 20b therein, the conductive members 2A to 2F may be linearly formed.

(4) The pilot hole 20c1, the through-holes 22a1 and 20d1, or the groove portion 20d2 of the conductive members 2A to 2F may be appropriately omitted.

The board fixing structure according to the embodiments disclosed here can be utilized as a support structure of a circuit board incorporated in a vehicle sensor.

A feature of a board fixing structure according to an aspect of this disclosure resides in that the board fixing structure includes a resin-made holder, a metal-made terminal held by the holder, and a circuit board connected to the terminal, the terminal has a proximal end portion, a fixing portion extending from the proximal end portion and fixedly soldered to the circuit board, and a support portion extending from the proximal end portion and coming into contact with a rear surface of the circuit board so as to support the circuit board, and the fixing portion and the support portion are separated from each other in a plane direction of the circuit board.

As in this configuration, if both the fixing portion fixedly soldered to the circuit board and the support portion supporting the circuit board are extended from the proximal end portion, both of these can be processed using the same member. Accordingly, the number of components and the processing cost can be saved. Moreover, as in Reference 1, the board fixing structure includes not only the fixing portion, but also the support portion coming into contact with the rear surface of the circuit board so as to support the circuit board. Accordingly, the circuit board can be fixed in a stabilized state. As a result, for example, even in a case where an external force which causes misalignment to the circuit board is applied due to thermal expansion, a bending force applied to the fixing portion is received by the support portion. Therefore, a soldered portion is less likely to be broken.

Furthermore, according to this configuration, the fixing portion and the support portion are separated from each other in the plane direction of the circuit board. That is, the support portion supports the circuit board at a position different from that of the fixing portion. Accordingly, it is possible to prevent a disadvantage that soldering heat escapes via the support portion as in Reference 2. As a result, the solder is properly melted. Therefore, the circuit board can be satisfactorily fixed.

Another feature resides in that the portion has a linear portion and a bent portion bent from the linear portion.

As in this configuration, if the bent portion bent from the linear portion is formed in the fixing portion, the bent portion restrains the soldering heat from being transferred to the proximal end portion, and thus, the solder is properly melted. Therefore, the circuit board can be more satisfactorily fixed.

Another feature resides in that at least a portion of the proximal end portion is insert-molded to the holder, and a through-hole and/or a groove is formed in a portion of the proximal end portion, which is present inside the holder.

As in this configuration, if the through-hole and/or the groove are/is formed in the portion of the terminal, which is present inside the holder, a resin enters the through-hole or the like. Accordingly, the terminal is firmly fixed to the holder. As a result, the circuit board is reliably fixed by the terminal.

Another feature ides in that a plurality of the terminals are provided, and a center of the through-hole and/or the groove in the respective terminals is on the same plane parallel to a plane of the circuit board.

A thermal expansion coefficient of a resin configuring the holder different from a thermal expansion coefficient of metal configuring the terminal. Consequently, there is a possibility that thermal stress is applied in a direction in which the terminal is inclined. In this case, the through-hole or the like which the resin has entered serves as a starting point at which the terminal starts thermal expansion. Therefore, as in this configuration, if the center of the through-hole or the like disposed in a plurality of the terminals is set on the same plane parallel to the plane of the circuit board, the starting points of the thermal expansion of the terminals can be aligned at the same height. As a result, a dimensional change amount of the terminal due to the thermal expansion can be equalized. Therefore, without causing the circuit board to be deflected, the soldered portion can be prevented from being broken.

Another feature resides in that a plurality of the support portions are provided, and the fixing portion is disposed between the respective support portions.

As in this configuration, if the fixing portion is disposed between the support portions, both sides of the fixing portion are supported by the support portions. Therefore, the support balance is improved, and the circuit board can be more satisfactorily fixed.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A board fixing structure comprising:
a resin-made holder;
a metal-made terminal held by the holder; and
a circuit board connected to the terminal,
wherein the terminal has a proximal end portion, a fixing portion extending from the proximal end portion and fixedly soldered to the circuit board, and a support portion extending from the proximal end portion and coming into contact with a rear surface of the circuit board so as to support the circuit board, and
wherein the fixing portion and the support portion are separated from each other in a plane direction of the circuit board.

2. The board fixing structure according to claim 1,
wherein the fixing portion has a linear portion and a bent portion bent from the linear portion.

3. The board fixing structure according to claim 1,
wherein at least a portion of the proximal end portion is insert-molded to the holder, and
wherein a through-hole and/or a groove are/is formed in a portion of the proximal end portion, which is present inside the holder.

4. The board fixing structure according to claim 3,
wherein a plurality of the terminals are provided, and
wherein a center of the through-hole and/or the groove in the respective terminals is on the same plane parallel to a plane of the circuit board.

5. The board fixing structure according to claim 1,
wherein a plurality of the support portions are provided, and
wherein the fixing portion is disposed between the respective support portions.
